(19) United States
(12) Patent Application Publication
(10) Pub. No.: US 2012/0120702 A1
(43) Pub. Date: May 17, 2012

(54) POWER SAVING TECHNIQUE IN A CONTENT ADDRESSABLE MEMORY DURING COMPARE OPERATIONS

(76) Inventors: Christopher D. Browning, Inver Grove Heights, MN (US); David B. Grover, Eden Prairie, MN (US)

(21) Appl. No.: 12/945,842

(22) Filed: Nov. 13, 2010

(51) Int. Cl. G11C 15/04; G11C 5/14

(52) U.S. Cl. 365/49.17; 365/189.09

(57) ABSTRACT

An apparatus comprising a first circuit, a driver circuit and a memory circuit. The first circuit may be configured to generate a supply voltage that changes between (i) a first voltage when an input signal is in a first state and (ii) a second voltage when the input signal is in a second state. The driver circuit may be configured to generate a wordline signal in response to (i) the supply voltage, (ii) a clock signal and (iii) a select signal. The memory circuit may be configured to perform a read/write operation in a response to the wordline signal.

### FIELD OF THE INVENTION

The present invention relates to memory devices generally and, more particularly, to a circuit and/or method for implementing a power saving technique in a content addressable memory during compare operations.

### BACKGROUND OF THE INVENTION

Conventional content addressable memories (CAMs) consume large amounts of power during compare operations. The power used during compares is more than the power used during read or write operations. In most CAM memories, a vast majority of the time is spent doing compares. Reducing overall power usage for a compare helps reduce overall maximum power. FIG. 1 shows a circuit 10 illustrating a conventional wordline driver 12 and a conventional CAM cell 14.

Conventional approaches to reducing power used by a CAM include using MOSFET devices having different voltage thresholds VT to reduce leakage in non-critical circuitry or using pre-search techniques to reduce the total number of bits that have to be searched. The mixed voltage threshold VT solution is implemented in silicon and is used for all compare, read and write operations. Reducing power during all operations will reduce the overall performance (speed) of the CAM. Also, the read/write circuitry can only be slowed down so far. Even though most CAM operations are compares, the read/write functions still need to operate at the given design frequency. Using all high voltage threshold VT devices (for the largest static power savings) in a high-performance system is not practical.

The disadvantage of using mixed voltage threshold VT devices is that only circuits in the non-critical path are optimized for power without reducing performance. Such techniques only account for a small percentage of the total circuitry in a CAM. The disadvantage of using pre-search is that power consumption is only reduced in the circuits related to compare operations. Read and write circuits make up a large portion of the total CAM where such power reduction techniques are not effective. The pre-search technique only saves power in the compare circuitry. This will not affect the circuits related to read and write.

It would be desirable to implement a circuit and/or method for reducing power consumption during compare operations in CAM circuits by reducing power to read and/or write circuitry during the compare operations.

### SUMMARY OF THE INVENTION

The present invention concerns an apparatus comprising a first circuit, a driver circuit and a memory circuit. The first circuit may be configured to generate a supply voltage that changes between (i) a first voltage when an input signal is in a first state and (ii) a second voltage when the input signal is in a second state. The driver circuit may be configured to generate a wordline signal in response to (i) the supply voltage, (ii) a clock signal and (iii) a select signal. The memory circuit may be configured to perform a read/write operation in a response to the wordline signal.

The objects, features and advantages of the present invention include providing a circuit and/or method for implementing power savings in a CAM memory that may (i) power down read and/or write circuitry during compare operations, (ii) be implemented without reducing read or write performance and/or (iii) quickly transition between a compare operation and a read/write operation.

### BRIEF DESCRIPTION OF THE DRAWINGS

These and other objects, features and advantages of the present invention will be apparent from the following detailed description and the appended claims and drawings in which:

FIG. 1 is a diagram of a conventional CAM circuit;

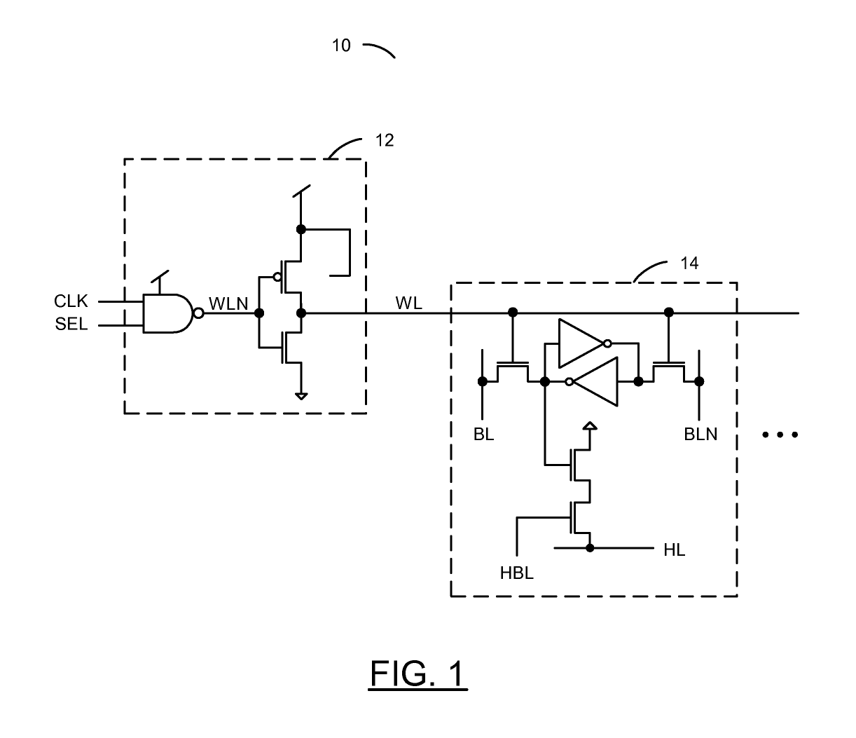

FIG. 2 is a block diagram of the present invention;

FIG. 3 is a more detailed diagram of the present invention;

FIG. 4 is a diagram of an alternate embodiment of the present invention;

FIG. 5 is a diagram of an implementation of the present invention with multiple wordline drivers; and

FIGS. 6a and 6b are diagrams of an implementation of the wordline driver header circuit with a number of threshold transistors.

### DETAILED DESCRIPTION OF THE PREFERRED EMBODIMENTS

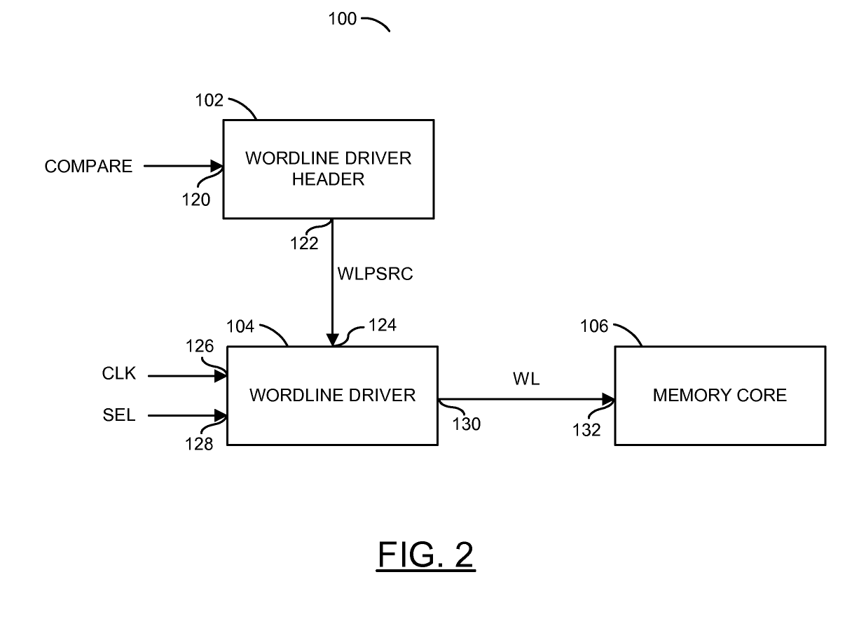

Referring to FIG. 2, a block diagram of a circuit 100 is shown in accordance with a preferred embodiment of the present invention. The circuit 100 generally comprises a block (or circuit) 102, a block (or circuit) 104 and a block (or circuit) 106. The circuit 102 may be implemented as a wordline driver header circuit. The circuit 102 may be configured to provide power to the circuit 104. The circuit 104 may be implemented as a wordline driver circuit. The circuit 106 may be implemented as a memory core circuit. The circuits 102, 104 and 106 may represent modules and/or blocks that may be implemented as hardware, software, a combination of hardware and software, or other implementations.

The circuit 102 may have an input 120 that may receive a signal (e.g., COMPARE) and an output 122 that may present a signal (e.g., WLPSRC). The circuit 104 may have an input 124 that may receive the signal WLPSRC, an input 126 that may receive a signal (e.g., CLK), an input 128 that may receive a signal (e.g., SEL) and an output 130 that may present a signal (e.g., WL). The circuit 106 may have an input 132 that may receive a signal WL. The signal WLPSRC may have a first voltage (e.g., a supply voltage VDD minus a threshold voltage VT) during compare operations. The signal WLPSRC may have a second voltage (e.g., a full rail of the supply voltage VDD) when a compare is not being performed. The signal WLPSRC may change between the two voltages in response to the state of the signal COMPARE. The signal CLK may be a clock signal that oscillates at a particular operating frequency. The signal SEL may be implemented as a select signal. The signal WL may be implemented as a wordline signal configured to initiate a read or a write to the memory circuit 106. The signal WL may be generated when both the signal SEL and the clock signal CLK are active.

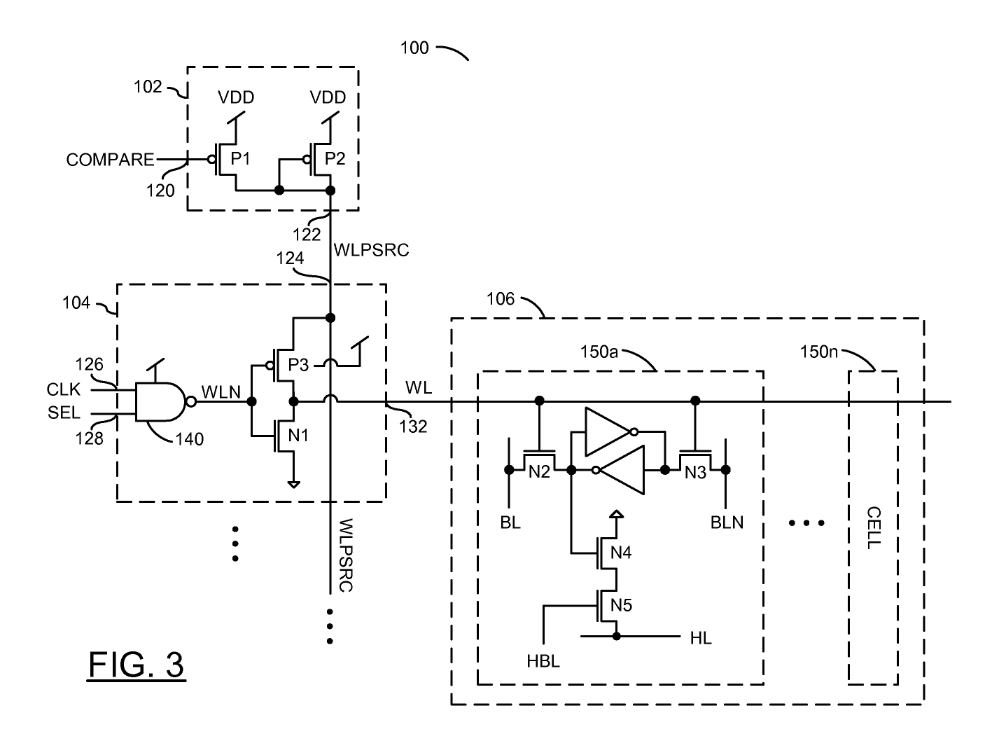

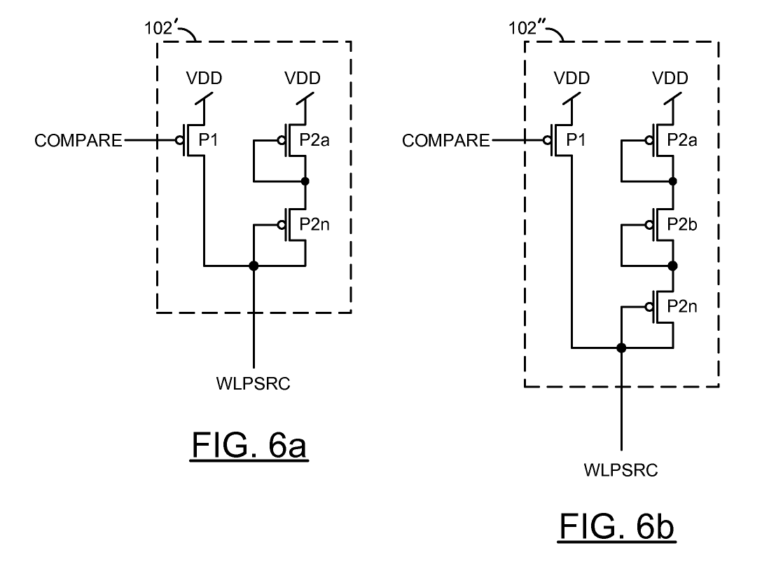

Referring to FIG. 3, a more detailed diagram of the circuit 100 is shown. The circuit 102 is shown comprising a transistor P1 and a transistor P2. The transistor P1 may have a gate that may receive the signal COMPARE, a source that is generally connected to a supply voltage VDD and a drain that is generally connected to the output 122. The transistor P2 may have a gate that is generally connected to the output 122, a source that is generally connected to the supply voltage VDD and a drain that is generally connected to the output 122. The transistor P2 is generally connected configured as a diode. In one example, the transistor P2 may be connected as a diode connected PFET. However, a diode connected NFET may be implemented. In one example, the transistor P1 and the transistor P2 may be implemented as PFET devices. However, other transistor types may be implemented to meet the design criteria of a particular implementation. Also, more than one transistor P2 may be implemented to provide a voltage drop of more than one voltage threshold VT (to be described in more detail in connection with FIGS. 6a and 6b).

The transistor P2 may provide a voltage drop equal to the threshold voltage VT of the transistor P2. In general, if the signal COMPARE enables the transistor P1, the signal WLPSRC may be a voltage generally equal to the supply voltage VDD minus the threshold voltage VT of the transistor P2. When the signal COMPARE does not enable the transistor P1, the signal WLPSRC may be a voltage equal to the full supply voltage VDD by passing the supply voltage VDD through the transistor P1 without the voltage threshold drop VT of the transistor P3.

The circuit 104 generally comprises a circuit 140, a transistor P3 and a transistor N1. The circuit 140 may be implemented as a logic gate. In one example, the circuit 140 may be implemented as a NAND gate. However, other types of gates may be implemented to meet the design criteria of a particular implementation. The gate 140 may receive the signal CLK and the signal SEL. The gate 140 may generate a signal (e.g., WLN). The signal WLN may be presented to the gate of the transistor P3 and the gate of the transistor N1. A source in the transistor P3 may receive the signal WLPSRC. A drain of the transistor P3 may be connected to the output 132 to generate the signal WL. The transistor N1 may have a gate that receives the signal WLN, a source connected the output 132 to generate the signal WL and a drain connected to the ground. The transistor P3 may also have a bulk node that may be connected to the supply voltage VDD. By connecting the bulk node to the supply voltage VDD, rather than directly to the voltage WLPSRC, the circuit 100 may provide maximum power savings. For example, when the voltage to the bulk node is higher than the voltage VLPSRC, the overall source to drain leakage of the transistor P3 is normally reduced.

The memory 106 generally comprises a plurality of cells 150a-150n. Each of the cells generally receives the signal WL. Details of the cell 150a are shown. The cell 150n is shown without details, but may have a similar implementation as the cell 150a. The cell 150a generally comprises a transistor N2, a transistor N3, a transistor N4 and a transistor N5. The transistor N2 may be connected to a bit line (e.g., BL). The transistor N3 may be connected to an inverted bit line (e.g., BLN). The transistor N5 may have a drain connected to a line (e.g., HL) and a gate connected to another line (e.g., HBL). The line HL and the line HBL may be implemented as hierarchical bit lines.

A circuit 100 has three main operations—read, write, and compare. A write operation is normally used to load data into the CAM memory 106. A read operation may allow a user to verify the contents of each address of the CAM memory 106. The compare operation may be used to compare the data-in bits to the contents stored in the memory 106. The compare may provide a user an output identifying which, if any, of the entries matches the data-in bits.

Content addressable memories consume a large amount of total power when executing compare operations. The circuit 100 may reduce the static power used during compare operations, when read or write operations do not normally occur. Since read or write operations do not normally occur when a compare operation is running, the circuit 100 does not limit read or write performance. In general, the circuit 100 may reduce and/or shut down power to read/write circuits during compare operations. Power may be restored to the read/write circuitry when the next read and/or write occurs. Since power is restored for read and/or write operations, the circuit 100 does not limit or reduce the overall CAM performance.

Compare operations make up most of the commands issued in a CAM when compared with read or write operations. Read or write operations do not normally occur during compare operations. The circuit 100 may reduce read/write static power while an active compare command is running. The largest static current in the read/write circuits is normally used by the final PFET in the wordline driver 104. When a compare operation is active, the source of the final PFET transistor P3 has an operating voltage reduced from full rail (VDD) to VDD minus a threshold voltage VT. The lower operating voltage reduces static current through the PFET transistor P3. The lower operating voltage may save up to ⅓ (or more) of the static power used by the wordline driver circuit 104.

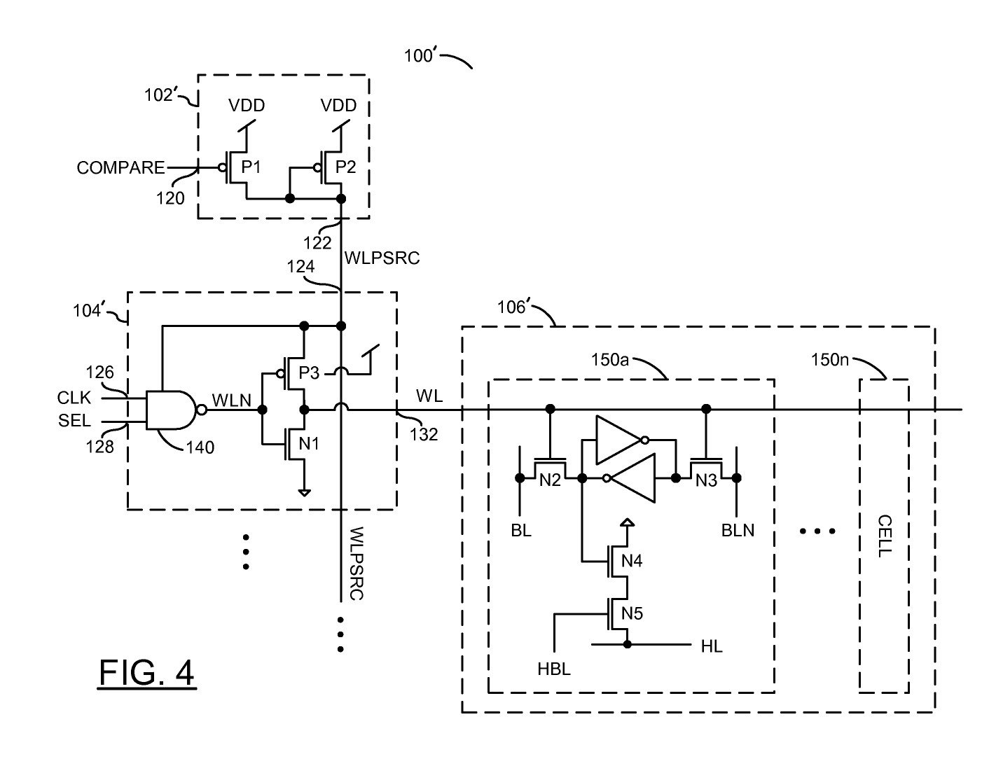

Referring to FIG. 4, a circuit 100′ is shown illustrating an alternate embodiment of the present invention. The voltage of the various devices in the wordline driver 104′ may be reduced by the threshold voltage VT to provide additional power savings. For example, the circuit 104 is shown connected to the signal WLPSRC. Since the wordline driver 104 does not normally need to operate during a compare operation, using the signal WLPSRC to power the circuit 104 does not normally reduce performance.

In one example, lowering the operating voltage VDD by a threshold voltage VT has the advantage of only discharging the signal WLPSRC by approximately 0.12V (e.g., when using FET transistors). In another example, lowering the operating voltage VDD by a threshold voltage VT has the advantage of only discharging the signal WLPSRC by approximately 0.3V (e.g., when using non-FET transistors). However, other voltage drops may be obtained depending on the design criteria of a particular implementation. For example, in a typical 40 nm technology, a typical voltage of 0.9V may provide an operating voltage at room temperature (e.g., 25 C) of 0.11V. Such a voltage may vary between 0.81V and 0.99V over process variations to provide an operating voltage at a low temperature (e.g., at 0 C) of 0.121V, and an operating voltage at a high temperature (e.g., 125 C) of 0.169V. A typical average operating voltage may be an average of such voltages (e.g., approximately 0.133V). However, other process technologies and/or operating voltages may be implemented to meet the design criteria of a particular implementation. Regardless of the technology implemented, the threshold voltage VT may reduce the overall operating voltage used by the circuit 100.

The signal WLPSRC normally changes from the supply voltage VDD to the lower voltage VDD-VT when the signal COMPARE indicates the circuit 100 changes from a read/write operation to a compare operation. The charge up time needed when going from a compare operation to a read or write operation is minimized by not dropping the voltage of the signal WLPSRC to zero. Also, implementing a relatively small charge up voltage may reduce potentially large current spikes on the supply voltage VDD when transitioning from a compare operation to a read/write operation. In particular, if the net were to be fully discharged (e.g., starting at 0V) a potential current spike to charge to full rail may be very large. However, in certain designs, implementing a voltage drop greater than a threshold voltage VT may be useful. For example, a 2VT, 3VT, etc. drop may be implemented (to be described in more detail in connection with FIG. 6).

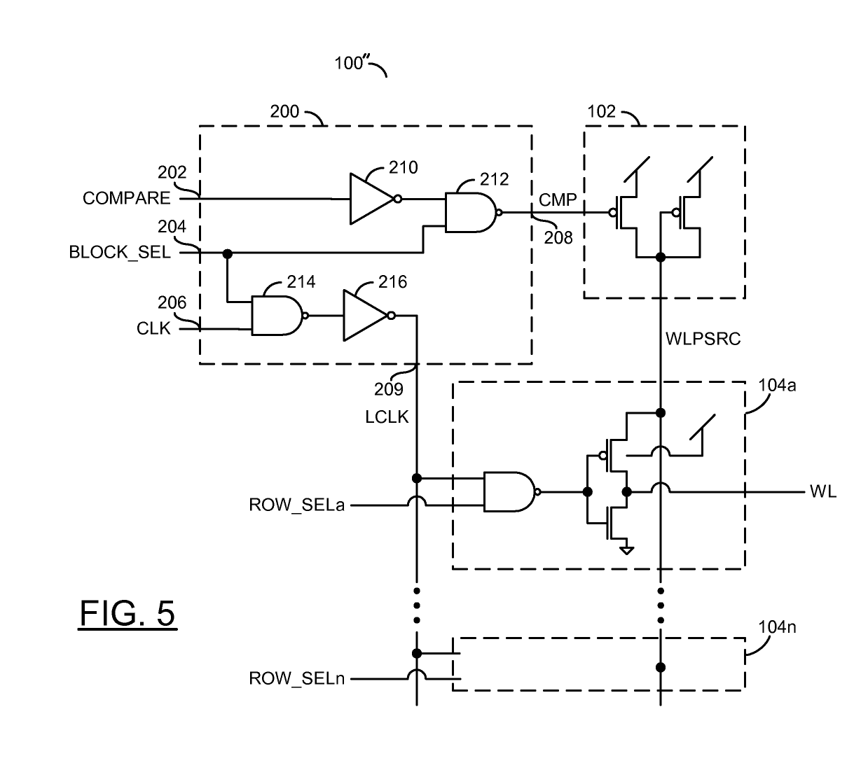

Referring to FIG. 5, a diagram of a circuit 100″ illustrating an implementation of multiple wordline driver circuits 104a-104n is shown. The circuit 100″ includes a logic circuit 200. The logic circuit 200 may have an input 202 that may receive the signal COMPARE, an input 204 that may receive a signal (e.g., BLOCK_SEL), an input 206 that may receive the signal CLK, an output 208 that may present a signal (e.g., CMP), and an output 209 that may present a signal (e.g., LCLK). The circuit 200 may be implemented as a control circuit. The signal CMP may be an active low signal that may be generated when the signal COMPARE is a logical “0” and the signal BLOCK_SEL is a logical “1”. However, other logical arrangements may be implemented. The signal COMPARE may be gated with the signal BLOCK_SEL to generate the signal CMP. The signal LCLK may be a clock signal generated in response to the clock signal CLK and the signal BLOCK_SEL. The circuit 200 generally comprises a gate 210, a gate 212, a gate 214, and a gate 216. The gates 210 and 216 may be implemented as inverters. The gates 212 and 214 may be implemented as NAND gates. However, other gates may be implemented to meet the design criteria of a particular implementation.

The signal BLOCK_SEL may be a predecoded address signal configured to control the particular wordline driver circuits 104a-104n that receive the signal WLPSRC. A signal ROW_SELa-n may be a logical AND of the predecoded addresses such that only one row is selected at a particular time. In such an implementation, a certain range of wordline driver circuits 104a-104n may receive the signal WLPSRC operating at full rail voltage VDD. Selectively activating the wordline driver circuits 104a-104n may save static power during read/write operations.

Referring to FIGS. 6a and 6b, diagrams of an alternate circuit 102′ and 102″ are shown implementing a number of transistors P2a-P2n. By implementing a number of transistors P2a-P2n, the particular voltage drop of the signal WLPSRC, compared with the supply voltage VDD, may be varied by a number of threshold voltages VT. For example, if a voltage drop of two threshold voltages VT is needed, then two transistors (e.g., P2a and P2n) may be implemented as shown in FIG. 6a. If a voltage drop of three threshold voltages VT is needed, then three transistors (e.g., P2a, P2b, and P2n) may be implemented as shown in FIG. 6b. The particular number of transistors P2a-P2n implemented may be varied to meet the design criteria of a particular implementation.

The various signals of the present invention are generally “on” (e.g., a digital HIGH, or 1) or “off” (e.g., a digital LOW, or 0). However, the particular polarities of the on (e.g., asserted) and off (e.g., de-asserted) states of the signals may be adjusted (e.g., reversed) to meet the design criteria of a particular implementation. Additionally, inverters may be added to change a particular polarity of the signals.

The present invention may also be implemented by the preparation of ASICs (application specific integrated circuits), Platform ASICs, FPGAs (field programmable gate arrays), PLDs (programmable logic devices), CPLDs (complex programmable logic device), sea-of-gates, RFICs (radio frequency integrated circuits), ASSPs (application specific standard products), one or more integrated circuits, one or more chips or die arranged as flip-chip modules and/or multi-chip modules or by interconnecting an appropriate network of conventional component circuits, as is described herein, modifications of which will be readily apparent to those skilled in the art(s).

While the invention has been particularly shown and described with reference to the preferred embodiments thereof, it will be understood by those skilled in the art that various changes in form and details may be made without departing from the scope of the invention.

1. An apparatus comprising:
a first circuit configured to generate a supply voltage that changes between (i) a first voltage when an input signal is in a first state and (ii) a second voltage when said input signal is in a second state;
a driver circuit configured to generate a wordline signal in response to (i) said supply voltage, (ii) a clock signal and (iii) a select signal; and
a memory circuit configured to perform a read/write operation in a response to said wordline signal.

2. The apparatus according to claim 1, wherein said memory circuit comprises a plurality of cells each configured to perform read/write operations.

3. The apparatus according to claim 1, wherein said memory circuit is configured as a content addressable memory (CAM) configured to operate in (i) a search mode and (ii) a read/write mode.

4. The apparatus according to claim 3, wherein said first circuit generates (i) said first voltage when said memory operates in said search mode and (ii) said second voltage when said memory operates in said search mode.

5. The apparatus according to claim 3, wherein said first circuit reduces the overall power used by said memory by using said second voltage during compare/search operations.

6. The apparatus according to claim 1, wherein said first voltage comprises a supply voltage and said second voltage comprises a supply voltage minus a transistor threshold voltage.

7. The apparatus according to claim 1, wherein said first voltage comprises a supply voltage and said second voltage comprises a supply voltage minus a plurality of threshold voltages.

8. The apparatus according to claim 1, wherein said first circuit comprises a first transistor configured as a diode, and a second transistor configured to receive said input signal.

9. The apparatus according to claim 1, wherein said driver circuit comprises a wordline driver circuit.

10. The apparatus according to claim 9, wherein said apparatus comprises a plurality of said wordline driver circuits.

11. The apparatus according to claim 10, wherein said plurality of wordline driver circuits are selectively activated.

12. The apparatus according to claim 1, further comprising:
a control circuit configured to generate said input signal in response to (i) a second input signal, (ii) a select signal, and (iii) a second clock signal.

13. The apparatus according to claim 12, wherein said control circuit is configured to generate said second clock signal in response to said clock signal and said select signal.

14. The apparatus according to claim 1, wherein said apparatus is implemented as one or more integrated circuits.

15. An apparatus comprising:
means for generating a supply voltage that changes between (i) a first voltage when an input signal is in a first state and (ii) a second voltage when said input signal is in a second state;
means for generating a wordline signal in response to (i) said supply voltage, (ii) a clock signal and (iii) a select signal; and
means for performing a read/write operation in a response to said wordline signal.

16. A method for reducing power in a memory, comprising the steps of:
(A) generating a supply voltage that changes between (i) a first voltage when an input signal is in a first state and (ii) a second voltage when said input signal is in a second state;
(B) generating a wordline signal in response to (i) said supply voltage, (ii) a clock signal and (iii) a select signal; and
(C) performing a read/write operation in a response to said wordline signal.

17. The method according to claim 16, further comprising the step of:
generating a plurality of wordline signals, each configured to control a respective one of a plurality of wordlines of said memory.

18. The method according to claim 16, wherein said first voltage comprises a supply voltage and said second voltage comprises a supply voltage minus a transistor threshold voltage.

19. The method according to claim 16, wherein said first voltage is used during a search mode and said second voltage is used during a search mode.
